(19) United States
(12) Patent Application Publication
(10) Pub. No.: US 2026/0030427 A1
(43) Pub. Date: Jan. 29, 2026

(54) METHOD FOR GENERATING CIRCUIT DESIGN FOR ASYNCHRONOUS CIRCUIT, AUTOMATED ASYNCHRONOUS CIRCUIT DESIGN TOOL, AND ASYNCHRONOUS CIRCUIT

(71) Applicant: Renesas Design (UK) Limited, Bourne End (GB)

(72) Inventors: Viktor KHOMENKO, Newcastle upon Tyne (GB); Marco SAUTTO, Zurich (CH); Danil SOKOLOV, Newcastle Upon Tyne (GB)

(73) Assignee: Renesas Design (UK) Limited, Bourne End (GB)

(21) Appl. No.: 18/782,228

(22) Filed: Jul. 24, 2024

(51) Int. Cl. G06F 30/392

(52) U.S. Cl. CPC G06F 30/392

(57) ABSTRACT

A computer-implemented method for generating a circuit design for an asynchronous circuit having an asynchronous finite state machine circuit is provided. The method includes receiving a first data file having state transition data that describes an asynchronous finite state machine. The method further includes generating, from the state transition data, a plurality of state data packages and one or more transition data packages. Each state data package is representative of a state of the asynchronous finite state machine. Each transition data package is representative of a transition between two states of the asynchronous finite state machine. The method further includes generating a second data file having circuit design data for the asynchronous circuit, thereby generating the circuit design for the asynchronous circuit.

The present disclosure relates to a computer-implemented method for designing an asynchronous circuit, and an asynchronous circuit.

### BACKGROUND

An asynchronous circuit is a circuit that does not require a clock signal for the synchronisation of its operation, and may be contrasted with synchronous circuits. Asynchronous circuits can operate quicker and more efficiently that corresponding synchronous circuits.

### SUMMARY

It is desirable to provide a method for the design of an asynchronous circuit. It is desirable to provide an improved asynchronous circuit.

According to a first aspect of the disclosure there is provided a computer-implemented method for generating a circuit design for an asynchronous circuit comprising an asynchronous finite state machine circuit, comprising executing on a processor the steps of receiving a first data file, the first data file comprising state transition data that describes an asynchronous finite state machine, generating, from the state transition data a plurality of state data packages, each of the plurality of state data packages being representative of a state of the asynchronous finite state machine, and one or more transition data packages, each of the one or more transition data packages being representative of a transition between two states of the asynchronous finite state machine, and generating a second data file comprising circuit design data for the asynchronous circuit, thereby generating the circuit design for the asynchronous circuit, by, for each of the plurality of state data packages, generating a circuit block data package comprising electrical circuit data for the design of an electrical circuit that is suitable for implementing an asynchronous finite state machine state as represented by the state data package, generating a wire data package for each of the one or more transition data packages, generating asynchronous finite state machine circuit data comprising the circuit block data packages and the wire data packages, and generating the circuit design data comprising the asynchronous finite state machine circuit data.

Optionally, the state transition data comprises the plurality of state data packages, and/or the one or more transition data packages.

Optionally, the asynchronous circuit is quasi delay insensitive.

Optionally, the circuit design for the asynchronous circuit comprises logic gates.

Optionally, the method is automated.

Optionally, the state transition data comprises an asynchronous finite state machine.

Optionally, generating the second data file comprising circuit design data for the asynchronous circuit comprises synthesizing the asynchronous circuit using a circuit synthesis tool.

Optionally, one of the circuit block data packages, as generated, comprises electrical circuit data for the design of an electrical circuit that is suitable for implementing an asynchronous finite state machine initial state.

Optionally, the electrical circuit suitable for implementing the asynchronous finite state machine initial state comprises an OR gate and an inverter.

Optionally, each of the circuit block data packages, as generated, comprises electrical circuit data that enables the electrical circuit to request a transition to another state of the asynchronous finite state machine.

Optionally, each of the circuit block data packages, as generated, comprises electrical circuit data that enables the electrical circuit to request a transition to another state of the asynchronous finite state machine when a condition is met.

Optionally, the condition is dependent on inputs as received by the asynchronous finite state machine circuit.

Optionally, the circuit design data comprises processing module data, the processing module data being data for the design of a processing module for processing the inputs prior to providing the inputs to the asynchronous finite state machine circuit.

Optionally, the processing module comprises one or more edge catching circuits, each of the one or more edge catching circuits being configured to process at least one of the inputs prior to providing the at least one input to the asynchronous finite state machine circuit by, for each of the at least one inputs, converting an edge into a level.

Optionally, Boolean logic is used to determine whether the condition is met.

Optionally, the inputs are non-persistent.

Optionally, the transition is requested via a wire to another electrical circuit, the wire being provided by one of the wire data packages.

Optionally, at least one of the circuit block data packages, as generated, comprises electrical circuit data for an arbiter circuit to arbitrate between a plurality of transition requests and then request the transition to another state of the asynchronous finite state machine when the condition is met and based on the arbitration.

Optionally, each of the circuit block data packages, as generated, comprises electrical circuit data for an arbiter circuit to arbitrate between a plurality of transition requests and then request the transition to another state of the asynchronous finite state machine when the condition is met and based on the arbitration.

Optionally, each of the circuit block data packages, as generated, comprises electrical circuit data that enables the electrical circuit to acknowledge that it has received a request from another state of the asynchronous finite state machine.

Optionally, each of the circuit block data packages, as generated, comprises electrical circuit data that enables the electrical circuit to initiate an action.

Optionally, the action is initiated by a handshake.

Optionally, the action comprises setting one or more outputs of the asynchronous circuit for controlling an analog circuit.

Optionally, the circuit design data comprises action processor data, the action processor data being data for the design of an action processor for performing the actions.

According to a second aspect of the disclosure there is provided a computer system configured as an automated asynchronous circuit design tool for generating a circuit design for an asynchronous circuit comprising an asynchronous finite state machine circuit, the computer system being configured to receive a first data file, the first data file comprising state transition data that describes an asynchronous finite state machine, generate, from the state transition data a plurality of state data packages, each of the plurality of state data packages being representative of a state of the asynchronous finite state machine, and one or more transition data packages, each of the one or more transition data packages being representative of a transition between two states of the asynchronous finite state machine, and generate a second data file comprising circuit design data for the asynchronous circuit, thereby generating the circuit design for the asynchronous circuit, by, for each of the plurality of state data packages, generating a circuit block data package comprising electrical circuit data for the design of an electrical circuit that is suitable for implementing an asynchronous finite state machine state as represented by the state data package, generating a wire data package for each of the one or more transition data packages, generating asynchronous finite state machine circuit data comprising the circuit block data packages and the wire data packages, and generating the circuit design data comprising the asynchronous finite state machine circuit data.

Optionally, the state transition data comprises the plurality of state data packages, and/or the one or more transition data packages.

It will be appreciated that the computer system of the second aspect may include features as set out in relation to the first aspect, and may include other features as described herein, in accordance with the understanding of the skilled person.

According to a third aspect of the disclosure there is provided an asynchronous circuit comprising an asynchronous finite state machine circuit comprising a plurality of circuit blocks, wherein each of the circuit blocks is configured to implement a state of an asynchronous finite state machine, and one or more wires, wherein each of the one or more wires is configured to enable communication between a pair of the circuit blocks for transitioning the asynchronous finite state machine between states.

Optionally, the asynchronous circuit is quasi delay insensitive.

Optionally, the asynchronous finite state machine comprises logic gates.

Optionally, one of the circuit blocks is configured to implement an asynchronous finite state machine initial state.

Optionally, the circuit block configured to implement the asynchronous finite state machine initial state comprises an OR gate and an inverter.

Optionally, each of the circuit blocks is configured to request a transition to another state of the asynchronous finite state machine.

Optionally, each of the circuit blocks is configured to request a transition to another state when a condition is met.

Optionally, the condition is dependent on inputs as received by the asynchronous finite state machine circuit.

Optionally, the asynchronous circuit comprises a processing module for processing the inputs prior to providing the inputs to the asynchronous finite state machine circuit.

Optionally, the processing module comprises one or more edge catching circuits, each of the one or more edge catching circuits being configured to process at least one of the inputs prior to providing the at least one input to the asynchronous finite state machine circuit by, for each inputs, converting an edge into a level.

Optionally, the inputs are non-persistent.

Optionally, the transition is requested via one of the wires.

Optionally, at least one of the circuit blocks comprises an arbitration circuit configured to arbitrate between a plurality of transition requests.

Optionally, each circuit block is configured to acknowledge it has received a request from another state of the asynchronous finite state machine.

Optionally, each circuit block is configured to initiate an action.

Optionally, each circuit block is configured to initiate an action by a handshake.

Optionally, the action comprises setting one or more outputs of the asynchronous circuit for controlling an analog circuit.

Optionally, the asynchronous circuit comprises an action processor for performing the actions.

Optionally, the asynchronous circuit is configured as a controller.

Optionally, the asynchronous circuit is for controlling a switching converter.

It will be appreciated that the asynchronous circuit of the third aspect may include features as set out in relation to the first aspect and/or the second aspect, and may include other features as described herein, in accordance with the understanding of the skilled person.

### BRIEF DESCRIPTION OF THE DRAWINGS

The disclosure is described in further details below by way of example and with reference to the accompanying drawings in which:

FIG. 1A is a schematic of a synchronous finite state machine circuit;

FIG. 1B is a schematic of a known asynchronous finite state machine circuit;

FIG. 2 is graphical representation of an example asynchronous finite state machine;

FIG. 3A is a flow chart for a computer-implemented method for generating a circuit design for an asynchronous circuit comprising in accordance with a first embodiment of the present disclosure;

FIG. 3B is a schematic of a computer system for performing the steps of the method of FIG. 3A;

FIG. 3C is a schematic of a first data file;

FIG. 3D is a schematic of a second data file;

FIG. 4 is a schematic of an asynchronous circuit in accordance with a second embodiment of the present disclosure;

FIG. 5A is a state of an asynchronous finite state machine with M incoming arcs and N outgoing arcs;

FIG. 5B is a schematic of the asynchronous circuit that is a fragment of the circuit in

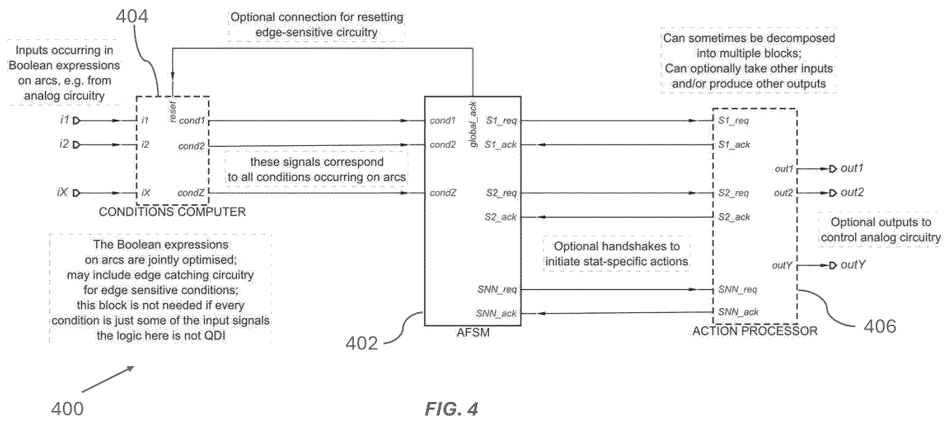

FIG. 4;

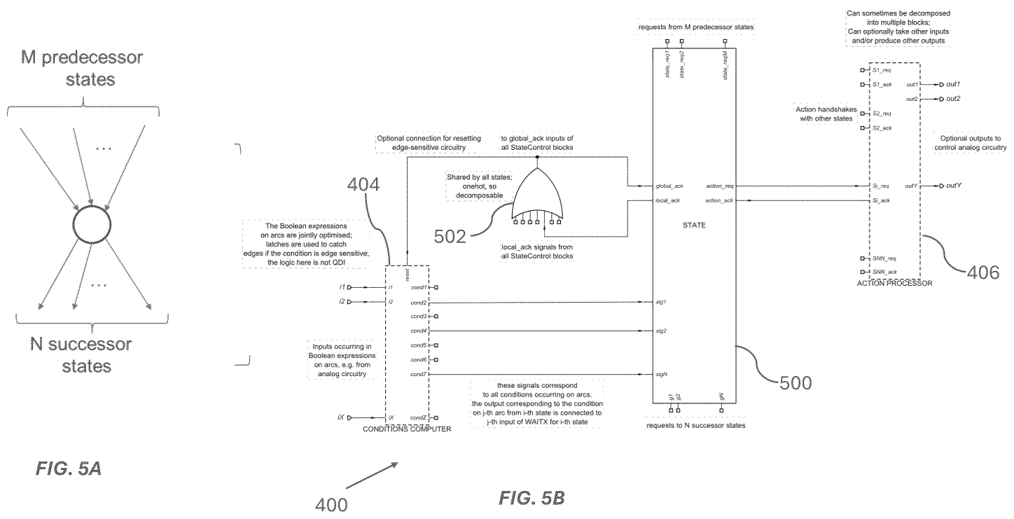

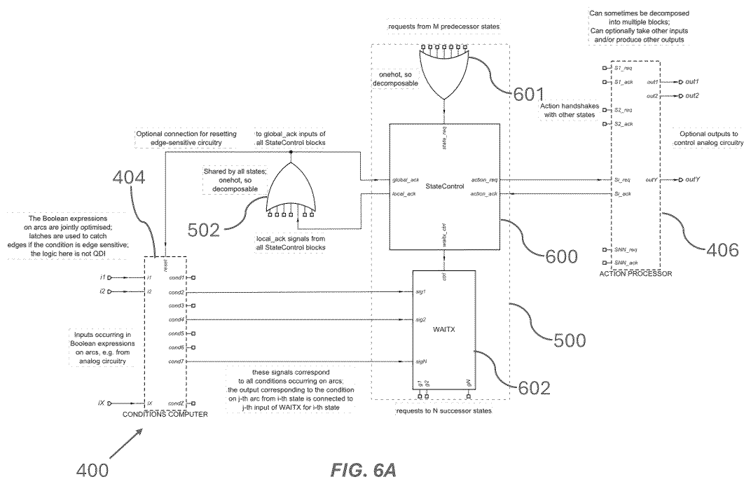

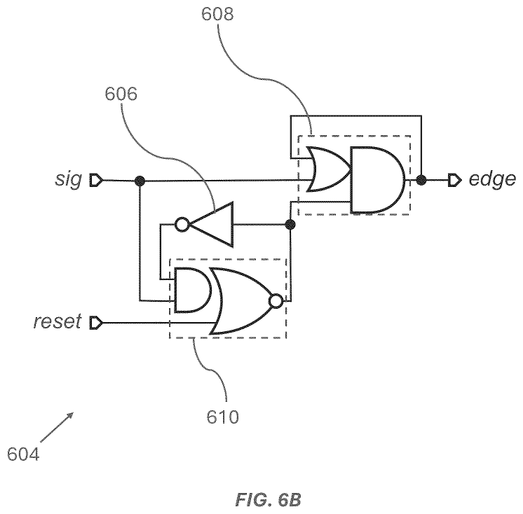

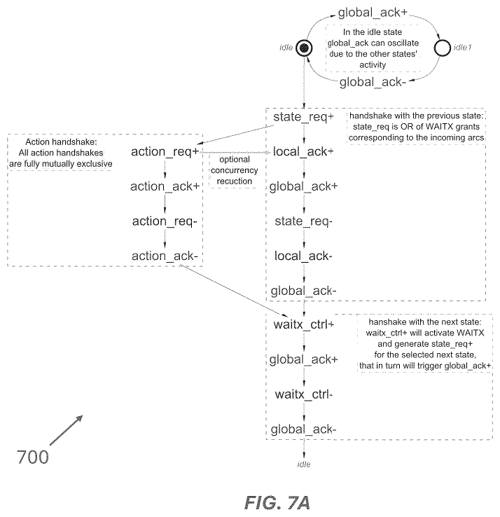

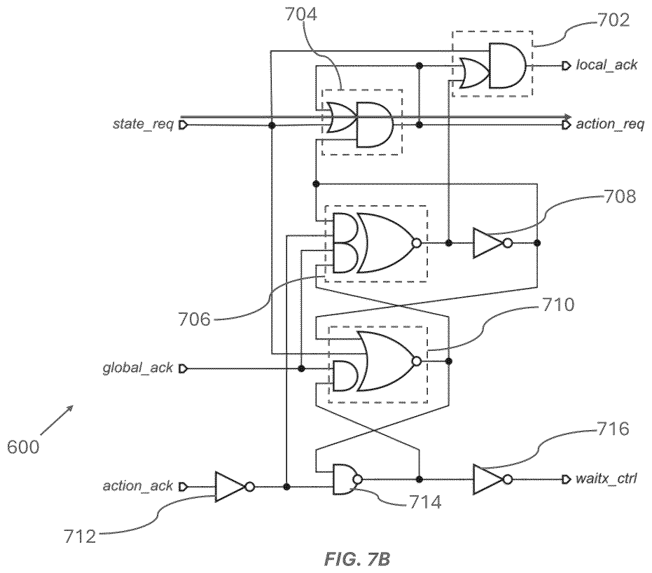

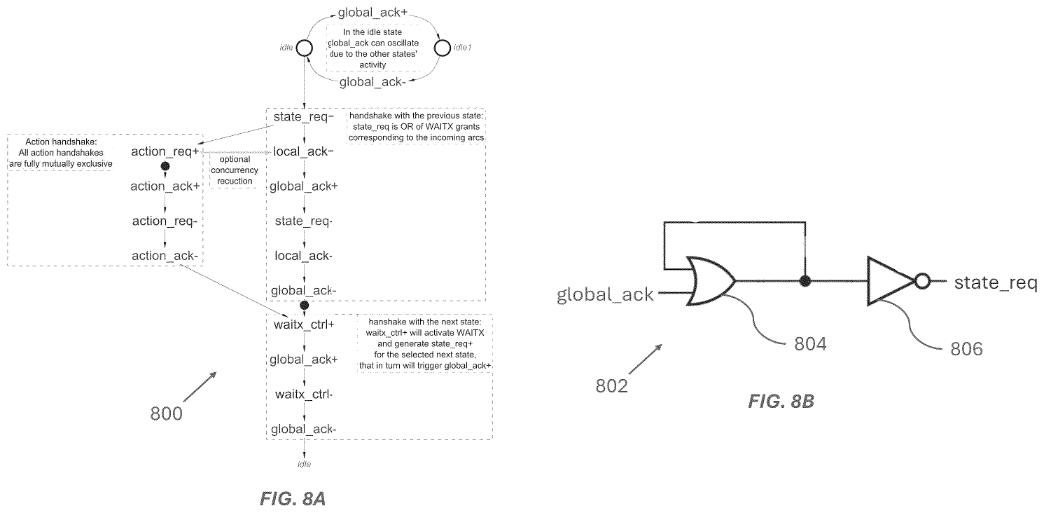

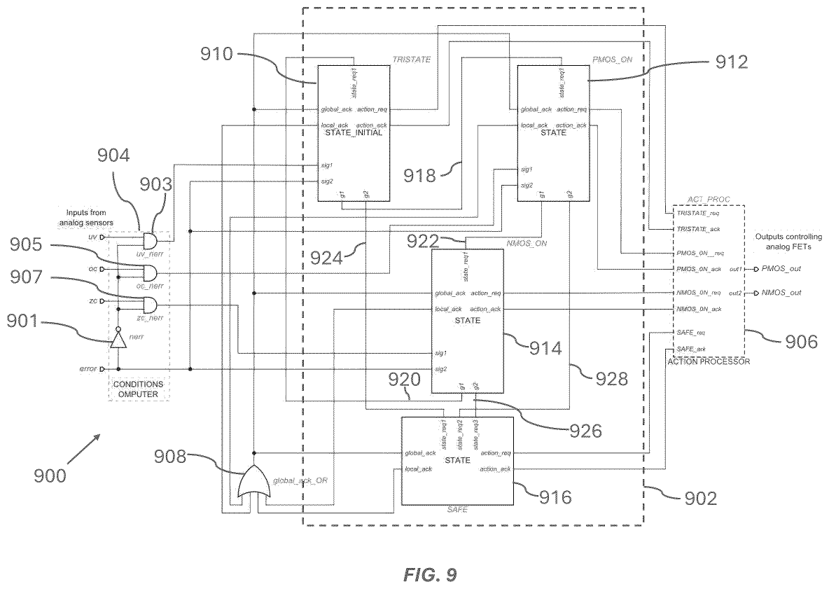

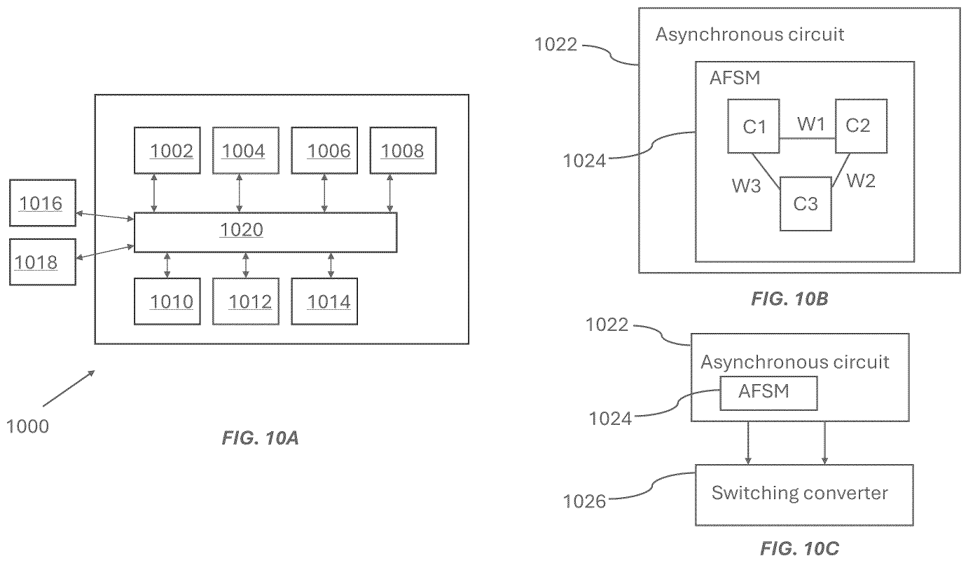

FIG. 6A is an alternative schematic of the asynchronous circuit as shown in FIG. 5B;

FIG. 6B is a schematic of an edge catching circuit;

FIG. 7A is a signal transition graph describing the behaviour of the state control block in FIG. 6A;

FIG. 7B is a schematic of a circuit design for a state control block in FIG. 6A;

FIG. 8A is a signal transition graph for an initial state control block;

FIG. 8B is a schematic of an alternative implementation for an initial state control block;

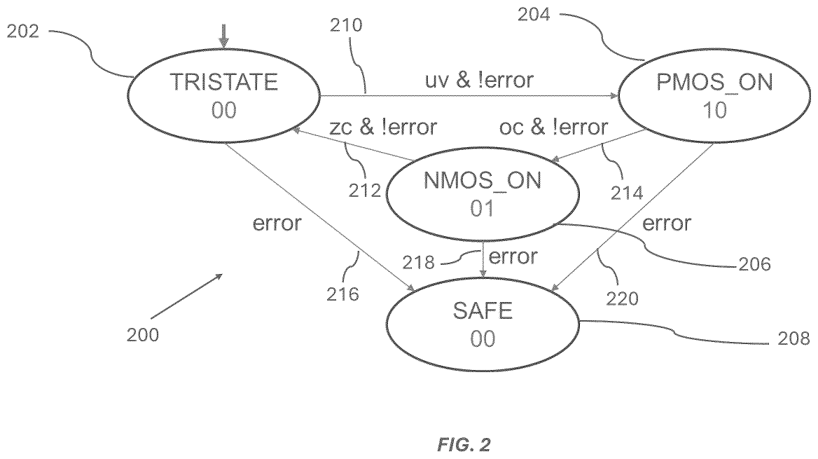

FIG. 9 is a schematic of an asynchronous circuit implementing the example AFSM in FIG. 2, in accordance with a third embodiment of the present disclosure;

FIG. 10A is a schematic of a computer system which comprises components for carrying out the methods of the present disclosure and in accordance with a fourth embodiment of the present disclosure;

FIG. 10B is a schematic of an asynchronous circuit in accordance with a fifth embodiment of the present disclosure; and

FIG. 10C is a schematic of a specific implementation of the asynchronous circuit for controlling a switching converter in accordance with a sixth embodiment of the present disclosure.

### DETAILED DESCRIPTION

A finite state machine (FSM) is a model that can be in one of several states. This may be based on inputs it receives and, for a synchronous implementation of an FSM, the state transitions may be controlled by a clock signal.

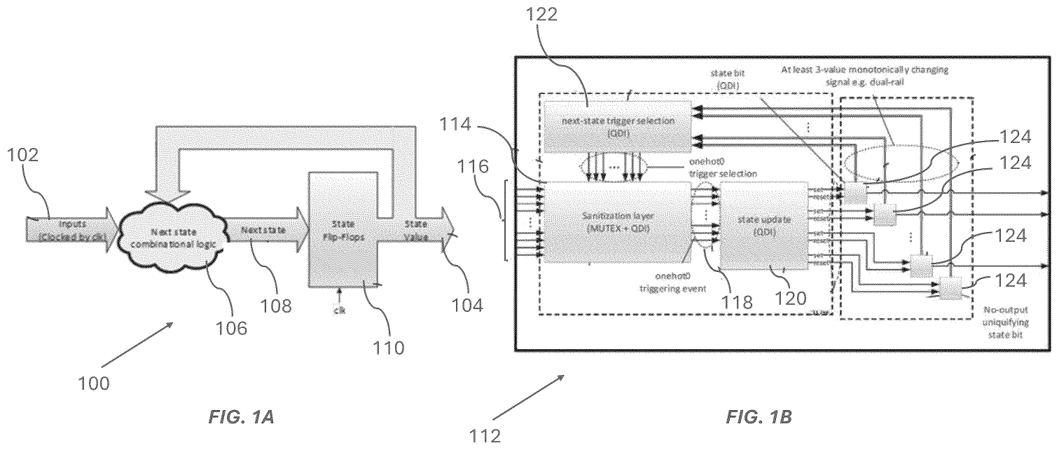

FIG. 1A is a schematic of a synchronous implementation of a finite state machine circuit 100. The circuit 100 receives inputs 102 and provides outputs 104. The circuit 100 comprises next state combinational logic 106 for receiving the inputs 102 and the outputs 104 and for providing a next state signal 108. The circuit 100 comprises state flip flops 110 that receive the next state signal 108 and a clock signal clk, with a state transition being triggered by the clock signal clk.

In operation, the clk event causes the state of the state flip flops 110 to update. Changes to the state and inputs 102 cause the next state to be re-calculated before the clk event updates the state again.

Using the circuit 100 requires the state update to wait until it receives the triggering clock event, which would provide a slow design with latency determined by the clock period. Asynchronous circuits do not have to wait for a triggering event from a clock to update the state of the circuit and hence can have a better latency than synchronous circuits.

FIG. 1B is a schematic of a known asynchronous finite state machine circuit 112 where the events from the clock, as described in relation to FIG. 1A, are substituted by events in a ring structure. The circuit 112 is an example of a design with a large number of interdependent outputs, with the outputs being taken from the state.

The occurrence of non-persistent signals within the circuit 112 can result in hazards, where the circuit 112 operates in an undesired way, for example because of different paths within the circuit 112 resulting in propagation delays that can cause incorrect outputs. Persistent signals ensure well-behaved operation of the circuit 112.

The circuit 112 comprises a sanitization layer 114 that has, at most, one sanitizer enabled. The sanitization layer 114 receives input signal 116 and provides output signals 118 that have been sanitized.

Real world inputs, such as the input signals 116 are rarely well-behaved, and therefore are filtered by the sanitization layer 114. The sanitization layer 114 receives the input signals 116, that may be non-persistent, and sanitizes the input signals 116 to provide output signals 118 that are persistent.

In the present example, the sanitizer implemented within the sanitization layer 114 may, for example, be a WAIT element for a single input signal, or a WAIT/arbiter construct for multiple input signals. The WAIT arbiter construct is configured to pick one of a set of potentially simultaneous events. WAIT and WAIT/arbiter elements may be implemented as described at https://workcraft.org/a2a/start and will be well known to the skilled person.

The circuit 112 comprises a state update block 120 that calculates the new state, which is fed back to a next-state trigger selection 122 to change the selected sanitizer. The circuit 112 further comprises state bits 124.

In the circuit 112, asynchronous finite state machine states have unique codes, and the states are represented by these codes. Moving from one state to another is achieved by computing a next state code based on the current code and input values. In the circuit 112, states are encoded using a dual-rail representations. The circuit 112 architecture has a global cycle which continuously computers the next state code.

An asynchronous circuit is Quasi Delay-Insensitive (QDI) if it operates correctly even when there are variations in the delay of signals within the circuit. QDI circuits are designed to be insensitive to delays that can occur due to variations in process, voltage, and temperature. Further information may be found here: https://en.wikipedia.org/wiki/Quasi-delay-insensitive_circuit.

The current practice is to divide the design of a QDI asynchronous circuit into two parts.

1. The QDI logic is defined using Signal Transition Graphs (STGs) [https://en.wikipedia.org/wiki/Signal_transition_graphs] and synthesized into a QDI circuit using a tool such as Petrify and MPSat [https://www.workcraft.org/help/synthesis].

2. The sanitization layer QDI logic requires that the environment within which it sits is compatible with the STG or STGs from which it was derived. This means that the ordering of input signal changes relative to output signal changes must be as specified by the STG or STGs. Real-world inputs are rarely well-behaved so must be filtered by the sanitization layer. The sanitization layer is under control of the QDI logic and turns non-persistent inputs into persistent signals. An example of this in is shown [https://www.workcraft.org/tutorial/design/hierarchical_buck/start] where the “WAIT*” blocks are the sanitization layer, and the “CYCLE” and “CHARGE” blocks are the QDI logic. The “WAIT*” blocks and other primitives are described in [https://www.workcraft.org/a2a/start] and [V. Khomenko, D. Sokolov, A. Mokhov, A. Yakovlev: “WAITX: an arbiter for non-persistent signals”, Proc. Asynchronous Circuits and Systems (ASYNC), 2017]. The QDI logic chooses which signals the sanitization layer is sensitive to. This ensures that only the expected inputs to the QDI logic can change.

FIG. 2 is a graphical representation of an example asynchronous finite state machine (AFSM) 200.

In the present example, the AFSM 200 functions as a controller for controlling switches, as may be used for a switching power converter, such as a buck converter. In the present example, one switch is a PMOS switch, and the other switch is an NMOS switch.

The AFSM 200 comprises four states 202, 204, 206, 208. States are typically represented by circles or ovals, but other shapes may also be used. The state 202 is an initial state (indicated by a short arrow pointing to the state 202), and represents the starting state of the AFSM 200. The AFSM 200 further comprises arcs 210, 212, 214, 216, 218, 220. Arcs represent transitions between states. Arcs are labelled by conditions which include Boolean expressions referring to inputs of the circuit (which may be coming from analog circuitry and may be non-persistent), and optionally can have extra annotation. For example, f may indicate that an edge rather than a level of the associated Boolean expression is used. The conditions on arcs in this example are all level-sensitive, but in general some of the conditions can be edge-sensitive.

The AFSM 200 in this example receives the following inputs: uv (undervoltage), oc (overcurrent), zc (zero crossing), error (error flag).

The actions undertaken in each state set a state-specific code (shown inside each state) on outputs PMOS_out and NMOS_out to control two analog FETs, but in general arbitrary actions can be used.

For example, in the NMOS_ON state, “01” denotes that the AFSM 200 outputs a signal for turning the PMOS switch off (denoted by the first “0”) and a signal for turning the NMOS switch on (denoted by the second “1”).

Operation of the AFSM 200 may be summarised as follows:

While uv signal is low—wait in TRISTATE, where both PMOS and NMOS are OFF (as denoted by “00”)

While uv is high—keep performing cycles of charging:
Switch PMOS ON and wait for oc to rise
When oc is high, switch PMOS OFF then switch NMOS ON and wait for zc to rise
When zc is high, switch NMOS OFF and enter TRISTATE

If at any point error is high, the AFSM 200 must ensure both PMOS and NMOS are OFF and go to the safe state where it does not react to any inputs.

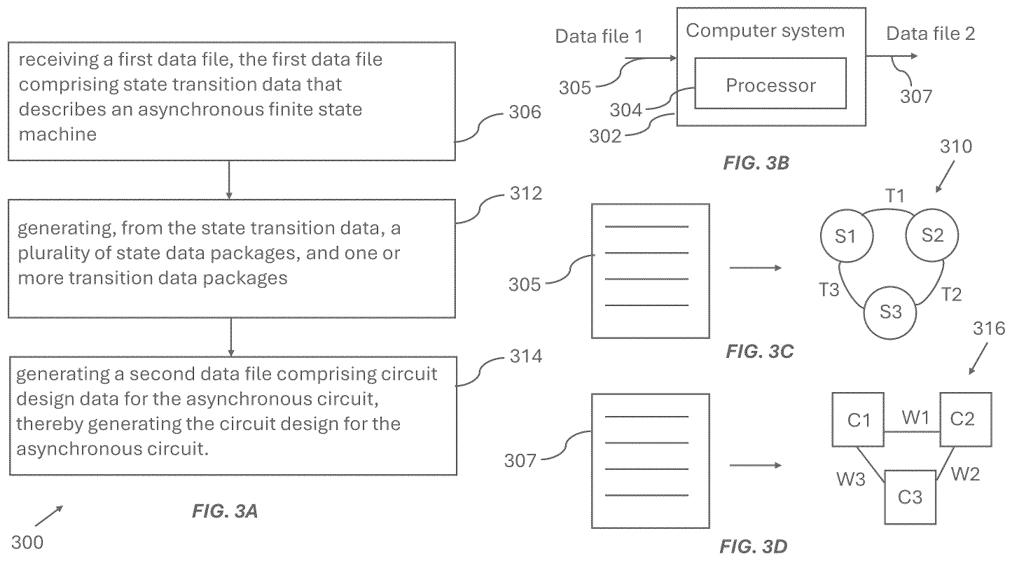

FIG. 3A is a flow chart for a computer-implemented method 300 for generating a circuit design for an asynchronous circuit comprising an AFSM circuit in accordance with a first embodiment of the present disclosure. The method 300 may be automated. FIG. 3B is a schematic of a computer system 302 comprising a processor 304 for performing the steps of the method 300.

The method 300 comprises receiving a first data file 305, at a step 306. FIG. 3C is a schematic of the first data file 305. The first data file 305 comprises state transition data that describes an AFSM. Information about states and arcs of the AFSM may be generated from the state transition data. For example, information may be generated by deriving, computing or extracting information from the data held within the state transition data.

In a specific embodiment, the state transition data may comprise a plurality of state data packages, with each state data package representing a state of the AFSM. The state transition data may comprise one or more transition data packages, with each transition data package representing a transition between states of the AFSM.

In a further embodiment the state transition data may comprise state data packages only, with the transition data packages being derivable from the state data packages. In a further embodiment, the state transition data may comprise the transition data packages only, with the state data packages being derivable from the transition data packages. In a further embodiment the state transition data may comprise a high level description of an AFSM that can be used to generate information on the AFSM.

In FIG. 3C, the state transition data of the first data file 305 is illustrated as an AFSM 310, which may have the format as illustrated in FIG. 2.

It will be appreciated that state transition data within the first data file 305 may be data in any suitable file format from which an AFSM description can be generated, for example by deriving, computing or extracting by a suitable software program.

In the present example there are three state data packages being representative of the states S1, S2, S3 of the AFSM, and there are three transition data packages being representative of the transitions T1, T2, T3.

The first data file 305 may be prepared by an engineer who determines the required functionality of the asynchronous circuit. The engineer may generate the state transition data themselves or may provide a different AFSM specification that is pre-processed to form the necessary state transition data. In a further embodiment, the first data file 305 may be automatically generated.

The method 300 further comprises generating, from the state transition data, each of the state data packages and each of the transition data packages, at a step 312.

Generating may be undertaken by deriving, computing or extracting one or both of the state data packages and the transition data packages, as discussed previously.

The method 300 further comprises generating a second data file 307 that comprises circuit design data for the asynchronous circuit, at a step 314. FIG. 3D is a schematic of the second data file 307.

The circuit design data within the second data file 307 may be in a suitable data format for extraction by an appropriate circuit design software package to form asynchronous circuit that can be manufactured, for example, by an integrated circuit fabrication process. Therefore, the circuit design data may comprise schematic and/or layout data for electrical circuits that are physically implementable. An example schematic of the circuit design data of an AFSM circuit 316 for implementing the AFSM 310 is shown in FIG. 3D.

The method 300 comprises generating the second data file 307 by generating a circuit block data package for each of the state data packages. Each circuit block data package comprises electrical circuit data for the design of an electrical circuit that is suitable for implementing an AFSM state as represented by one of the state data packages.

For example, the schematic of the AFSM circuit 316 shows electrical circuits C1, C2, C3. Electrical circuit C1 implements AFSM state S1; the electrical circuit C2 implements AFSM state S2; and the electrical circuit C3 implements AFSM state S3.

The method 300 comprises generating the second data file 307 by generating a wire data package for each of the transition data packages. For example, the schematic of the AFSM circuit 316 shows wires W1, W2, W3. The wire W1 is associated with the transition T1; the wire W2 is associated with the transition T2; and the wire W3 is associated with the transition T3. Each of the wires W1, W2, W3 represents an electrical connection between a pair of the electrical circuits C1, C2, C3.

The method 300 comprises generating the second data file 307 by generating AFSM circuit data comprising the circuit block data packages and the wire data packages, and generating the circuit design data comprising the AFSM circuit data. The AFSM circuit 316 shows a schematic representation of the circuit implementing the given AFSM component of the circuit design data.

Generation of the second data file 307 may comprise synthesizing the asynchronous circuit using a circuit synthesis tool.

The asynchronous circuit may be quasi delay insensitive (QDI), for example, in that the circuit can operate correctly regardless of gate delays, with wire forks assumed isochronic.

One or more of the circuits C1, C2, C3 may comprise logic gates configured to provide the required functionality.

In a physical implementation of the asynchronous circuit as represented by the schematic 316, a transition from one state to another state may be requested via one of the wires W1, W2, W3 to another of the electrical circuits C1, C2, C3. For example, and with reference to FIG. 3D, the AFSM may be set to state S1 by the electrical circuit C1; and the electrical circuit C1 may request a transition to state S2 by sending a request signal to the electrical circuit C2 via the wire W1.

When control is transferred to a state, the state may undertake an action associated with the state. For example, when control is provided to the electrical circuit C2, the action associated with the state S2 may be performed. The action may be arbitrary and can include doing nothing. Actions may be implemented by a separately designed circuit block and may be initiated by handshakes. In some embodiments, actions may include setting circuit outputs to state specific values to control analog circuitry. Each of the circuit blocks C1, C2, C3 may have circuitry to provide an active handshake to initiate an action associated with the state S1, S2, S3 that is associated with a given circuit block C1, C2, C3.

In summary, implementation of the method 300 results in each AFSM state S1, S2, S3 being translated to a circuit block, as provided by the circuit blocks C1, C2, C3. Furthermore, implementation of the method 300 results in each AFSM arc being translated to a single wire connecting circuit blocks. For example, the wire W1, relating to the transition T1 is used to connect the circuit blocks C1 and C2, which are related to the states S1 and S2, respectively. Each circuit block C1, C2, C3 may take conditions occurring on their out-arcs as inputs.

In summary, specific embodiments of the method 300 may be used to generate a QDI circuit implementing an AFSM as derived from a high level description (for example as provided by the first data file 305). The method 300 may be automated. In specific embodiments the asynchronous circuit may be used to control analog circuitry and therefore the inputs of the asynchronous circuit may be non-persistent and may use sanitization components to convert the inputs into persistent signals. The resultant asynchronous circuit, the design of which is generated as part of the method 300, may have a small latency on certain critical paths.

FIG. 4 is a schematic of an asynchronous circuit 400 comprising an AFSM circuit 402, the circuit design of which may be generated using the method 300, in accordance with a second embodiment of the present disclosure.

In a specific embodiment, each of the circuit block data packages may comprise electrical circuit data that enables the electrical circuit to request a transition to another state of the AFSM circuit 402. The request to transition to another state may occur when a condition is met, as may be determined by Boolean logic, and the condition may be dependent on an input received by the AFSM circuit 402.

In the present example, the inputs received by the AFSM circuit 402 are labelled cond1, cond2 and condz, with the input signals corresponding to all of the conditions of the arcs of the associated signal transition graph. One or more of the inputs cond1, cond2, condz may result in a request for a transition to another state of the AFSM circuit 402.

The circuit design data as generated using the method 300 may comprise processing module data for the design of a processing module 404 for processing the inputs prior to providing the inputs to the AFSM circuit 402. In the present example, the inputs i1, i2, iX are processed by the processing module 404 to provide the inputs cond1, cond2, condZ as received by the AFSM circuit 402. One or more of the inputs i1, i2, iX, cond1, cond2, condZ may be non-persistent.

Conditions occurring on AFSM circuit 402 arcs are computed by the processing module 404 and may be jointly optimised. For example, if the same condition occurs on different arcs, it may only need to be computed once; similarly if several conditions share a subfunction, it may only need to be computed once.

Each of the circuit block data packages may comprise electrical circuit data that enables the electrical circuit to initiate an action. In the schematic of the AFSM circuit the requests for actions are denoted as S1_req, S1_ack, SNN_req. The actions may be initiated by a handshake, with each request receiving an acknowledgement S1_ack, S2_ack, SNN_ack.

The circuit design data as generated using the method 300 may further comprise action processor data, the action processor data being data for the design of an action processor 406 for performing the actions. In the present example, the action processor 406 receives the action handshakes and initiates the actions as denoted by the outputs out1, out2, outY. The action may comprise setting one or more outputs of the asynchronous circuit 400, for example for controlling an analog circuit.

FIG. 5A shows a single state of an AFSM that has M incoming arcs from predecessor states and N outgoing arcs to successor states.

FIG. 5B is a further schematic of the asynchronous circuit 400 showing a single electrical circuit 500 of the AFSM circuit 402 that is representative of a single state of the AFSM. The electrical circuit 500 may request transition to another state as denoted by the outputs g1, g2, gN, with each output being provided to a distinct electrical circuit of the AFSM circuit 402. The electrical circuit 500 may receive transition requests from other electrical circuits as denoted by the inputs state_req1, state_req2, state_reqM.

The circuit fragment, being the electrical circuit 500 of FIG. 5B, corresponds to the state as shown in FIG. 5A.

The electrical circuit 500 may provide an acknowledgement (denoted local_ack) to indicate that it has received a request from another state, with the acknowledgement being provided to an OR gate 502 that receives local acknowledgements from all other electrical circuits implementing states of the AFSM and generates a global acknowledgement signal (denoted global_ack) for providing to all electrical circuits implementing AFSM states and, optionally, the processing module 404. In summary, each state block has an output local_ack—these signals from all state blocks are mutually exclusive and ORed into a global_ack signal that is taken as an input by each state block.

In the present example, the inputs i1, i2, iX are processed by the processing module 404 to provide the inputs cond1, cond2, cond3, cond4, cond5, cond6, cond7, condZ as received by the AFSM circuit 402.

FIG. 6A is an alternative schematic of the asynchronous circuit 400 as shown in FIG. 5B and showing a specific embodiment of the electrical circuit 500. The electrical circuit 500 comprises a state control block 600, an optional OR gate 601 and an optional arbiter 602. In the present embodiment, the arbiter is a WAITX component 602 arranged to arbitrate between a plurality of transition requests. The WAITX component 602 is an arbiter for non-persistent signals. One or more of the features of the electrical circuit 500 in the present embodiment may be present in one or more of the other electrical circuits 500 of the AFSM circuit 402 in accordance with the understanding of the skilled person.

The state control block 600 uses its signals action_req and action_ack to the action processor 406 for an action handshake.

At least one of the circuit block data packages as generated by the method 300 may comprise electrical circuit data for an arbiter circuit to arbitrate between a plurality of transition requests, then request the transition to another state when a condition is met and based on the arbitration. The arbiter circuit may be a WAITX component.

In one embodiment there may be a single WAITX component per electrical circuit (and therefore per AFSM state). However, in a further embodiment, there may be provided a single WAITX for the asynchronous circuit with additional circuitry being provided to select the necessary conditions computed by the processing module 404, depending on the currently active state.

The WAITX component 602 sanitizes conditions (which may be non-persistent) and arbitrates between them, for example as described in https://workcraft.org/a2a/start #waitx. The WAITX 602 is a scalable component—an N-way WAITX is required to arbitrate between N conditions.

If an AFSM state has no outgoing arcs, WAITX is not required. If an AFSM state has only one outgoing arc, a 1-way WAITX may be implemented as a simpler component called WAIT or WAIT0, see https://workcraft.org/a2a/start #wait_and_wait0.

During operation of the AFSM circuit 402 there will always be one active state, which initially is the initial state. An active state S may transfer control to another state S′ provided that there is an arc from S to S′ and an associated condition holds (for example, a Boolean expression either evaluates to true or has switched from false to true). If there are multiple arcs originating from S whose conditions hold, arbitration is performed to select a state to which control is transferred, for example by the WAITX component 602.

The WAITX component 602 may accept inputs corresponding to the conditions on the state's outgoing arcs, which may be taken from the processing module 404.

The state control component 600 may provide very low latency on the critical path. For example, in a specific embodiment, once the WAITX component 602 of the previous state makes a decision, i.e. state_req signal is received by state control component 602, that state control component 602 reacts by producing action_req signal with only a single gate delay.

Each state of the AFSM circuit 402 is mapped to a circuit fragment (an example circuit fragment being the electrical circuit 500) that comprises a state control block. The circuit fragment may further comprise an OR gate if there are two or more incoming arcs. The OR gate may be decomposed into smaller gates if necessary, e.g. if it has too many inputs to be implementable by a single gate. The circuit fragment may further comprise a WAITX component if there are two or more outgoing arcs. The WAITX component may be simplified to a WAIT component if there is a single outgoing arc, and may be omitted if there are no outgoing arcs.

If there is an arc between circuit blocks related to states S1 and S2, for example an i-th outgoing arc of S1 and j-th incoming arc of S2, then the i-th output of S1's WAITX component may be coupled to j-th input of S2's OR gate.

In a further embodiment, the AFSM circuit 402 may be configurable via firmware as follows:
A fixed number of state control blocks can be provided upfront, so the user's AFSM circuit 402 can use up to that number of states.
The processing module 404 and/or the action processor 406 may be customisable, for example by a user.
The action processor 406 for common actions, like setting some fixed values on the outputs depending on which AFSM state is currently active, may be pre-designed and may be configurable.
The connections between states can be reconfigured via firmware, or may be dynamically reconfigured.
N-way WAITX elements associated with state control blocks can have either fixed size (e.g. N=8) or alternatively the provided state blocks can have a range of WAITX sizes to save circuit area; the unused WAITX inputs may be set to 0 via firmware.
A single WAITX element may be shared by two or more state control blocks.

FIG. 6B is a schematic of an edge catching circuit 604. In a specific embodiment, the processing module 404 may comprise one or more edge catching circuits 604. The edge catching circuit 604 is configured to process one or more of the inputs prior to the inputs being provided the AFSM circuit 402 by converting each of the one or more inputs from an edge to a level. For example, if the edge catching circuit 604 detects a rising edge on its input sig, it outputs a high level on its output edge. The edge catching circuit 604 can be reset by a pulse on its input reset.

In the present example, the edge catching circuit 604 comprises an inverter 606, an OR-AND gate 608, and an AND-OR-INVERT gate 610.

If reset=1, the edge catching circuit sets edge=0. The signal global_ack from the AFSM circuit 402 can be used as reset. After reset is released, the circuit 604 may catch a rising edge of sig and set edge=1. The circuit 604 may be non-QDI and may glitch, with the glitches being filtered out by any arbiter circuits, such as the WAITX component 602, associated with the AFSM states.

The edge catching circuit 604 when used as part of the processing module 404 is used to implement edge-sensitive conditions, by converting edge sensitive conditions to level sensitive ones, so the AFSM circuit 402 can treat all the conditions as level sensitive.

If the AFSM circuit 402 has two or more states, there may be an OR gate that takes the local_ack signals from all the states and computes the global_ack signal that goes to all the states, for example as provided by the OR gate 502. The output of the OR gate 502 may be provided to the processing module 404 and may be used as a reset signal for the edge catching circuits used for edge sensitive conditions. The OR gate 502 may be decomposed into smaller gates if necessary, e.g. if it has too many inputs to be mapped directly to some gate in the gate library.

FIG. 7A is a signal transition graph (STG) 700 specifying the behaviour of the state control block 600.

The STG 700 is a type of Petri net in which transitions are labelled with the rising edges (denoted by a “+”) and falling edges (denoted by a “−”) of circuit signals.

A Petri net is a directed graph with two types of nodes: places and transitions. Places are represented by circles and transitions are represented by textual labels. Places can be connected to transitions by means of consuming arcs, and transitions can be connected to places by producing arcs. Producing and consuming arcs are denoted by arrows.

The state of a Petri net is determined by its marking. Marking is characterised by the number of tokens in each place of the Petri net. A token is typically denoted by a dot. The marking of a Petri net can evolve by means of a token game whose rules are as follows. A transition having all preceding places marked becomes enabled. An enabled transition may fire by reducing the number of tokens in every preceding place by one and increasing the number of tokens in every succeeding place by one as an atomic action. This firing leads to a new marking which defines the next state of the Petri net.

For simplicity, places with one consuming arc and one producing arc are often hidden, allowing arcs (with implicit places) directly between pairs of transitions. STGs are a convenient model for capturing causality (order of events), concurrency (interleaving of independent events) and conflict (choice of one scenario from several possibilities) relations on circuit signals.

Interpretation of STGs of the type presented herein will be well understood by the skilled person.

FIG. 7B is a schematic of a circuit design for the state control block 600 as may be included as part of the second data file 307.

The state control block 600 comprises logic gates 702, 704, 706, 708, 710, 712, 714, 716. In the present example, the critical path from state_req to action_req is a single gate, being the gate 704.

It will be appreciated that alternative circuit designs may also provide the functionalities as described by the STG 700 and the state control block 600 as shown in FIG. 7B is one possible implementation. For example, the inverter 712 may be simplified away by using negative signalling depending on the implementation of the action processor 406. Additionally, as the WAITX 602 has an inverter as its ctrl input, the inverter 716 may be simplified away. Other simplifications can be used as would be clear to a skilled person, or as performed by software tools.

FIG. 8A is a signal transition graph (STG) 800 for the initial state control block. This may result in the same circuit design as shown in FIG. 7B, but be differently initialised.

FIG. 8B is a schematic of an alternative implementation for an initial state control block 802 comprising an OR gate 804 and an inverter 806. In the present example, the initial state control block 802 is used to transfer control to a further initial state control block corresponding to the initial sate of the AFSM but implemented in the same way as any of the other state control blocks, such as is shown in FIG. 7B.

In a specific embodiment of the method 300, one of the circuit block data packages, as generated, may comprise electrical circuit data that enables the electrical circuit to set the AFSM to an initial state, for example the control block 802.

FIG. 9 is a schematic of an asynchronous circuit 900 comprising an AFSM circuit 902, the circuit design of which may be generated using the method 300, in accordance with a third embodiment of the present disclosure.

The asynchronous circuit 900 is an example circuit for implementing the AFSM 200 as presented in FIG. 2. The circuit design as included in the second date file 307 through application of the method 300 may be generated by providing the AFSM 200 as part of the first data file 305. It will be appreciated that the asynchronous circuit 900 is a specific implementation of the general representation provided by the asynchronous circuit 400.

The asynchronous circuit 900 comprises a processing module 904 for processing the inputs prior to providing the inputs to the AFSM circuit 902. The processing module 904 functions substantially as described for the processing module 404 in accordance with the understanding of the skilled person. The inputs are uv, oc, zc and error, as previously described in relation to the AFSM 200.

In the present example, the processing module 904 comprises an inverter 901 and AND gates 903, 905, 907.

The asynchronous circuit 900 further comprises an action processor 906 for performing the actions. The action processor 906 functions substantially as described for the action processor 406 in accordance with the understanding of the skilled person. In the present example, the outputs of the action processor 906 are the control signals PMOS_out, NMOS_out for controlling the analog FETs.

The asynchronous circuit 900 further comprises an OR gate 908 that functions substantially as described for the OR gate 601, in accordance with the understanding of the skilled person.

The AFSM circuit 902 comprises an electrical circuit 910 that is associated with the state 202; an electrical circuit 912 that is associated with the state 204; an electrical circuit 914 that is associated with the state 206; and an electrical circuit 916 that is associated with the state 208. The AFSM circuit 902 further comprises a wire 918 that is associated with the transition 210; a wire 920 that is associated with the transition 212; a wire 922 that is associated with the transition 214; a wire 924 that is associated with the transition 216; a wire 926 that is associated with the transition 218; a wire 928 that is associated with the transition 220.

Each of the electrical circuits 912-916 may be implemented using the state control block 600 and an arbiter, such as the WAITX component 602. In a further embodiment, each electrical circuit 912-916 may comprise the state control block 600, and the AFSM circuit 902 may comprise a single arbiter for providing an arbitration function for one or more of the electrical circuits 912-916.

In a specific embodiment, the electrical circuit 916 may comprise an OR gate as it has two or more incoming arcs (state_req1, state_req2, state_req3). It will be appreciated that in further embodiments, one or more of the electrical circuits 910-914 may also comprise OR gates for receiving inputs.

In the present embodiment, the electrical circuit 910 is associated with the initial state 202 and may be implemented as described in relation to FIG. 8A and/or FIG. 8B, in accordance with the understanding of the skilled person.

FIG. 10A is a schematic of a computer system 1000 which comprises components for carrying out the methods of the present disclosure. The computer system 1000 comprises a module 1002 which is configured as an automated asynchronous circuit design tool in accordance with a fourth embodiment of the present disclosure.

The computer system 1000 may comprise a processor 1004, a storage device 1006, RAM 1008, ROM 1010, a data interface 1012, a communications interface 1014, a display 1016, and an input device 1018. The computer system 1000 may comprise a bus 1020 to enable communication between different components.

The computer system 1000 may be configured to load an application. The instructions provided by the application may be carried out by the processor 1004. The application may be the automated asynchronous circuit design tool.

A user may interact with the computer system 1000 using the display 1016 and the input device 1018 to instruct the computer system 1000 to implement the methods of the present disclosure in the design of an asynchronous circuit.

FIG. 10B is a schematic of an asynchronous circuit 1022 comprising an AFSM circuit 1024 in accordance with a fifth embodiment of the present disclosure. The AFSM circuit 1024 comprises a plurality of circuit blocks C1, C2, C3, where each of the circuit blocks is configured to set the AFSM to a state associated with that particular circuit block C1, C2, C3. The AFSM circuit 1024 further comprises one or more wires W1, W2, W3. Each of the one or more wires W1, W2, W3 enables communication between a pair of circuit blocks C1, C2, C3 for transitioning the AFSM circuit 1024 between states. The asynchronous circuit 1022 may function as a controller.

FIG. 10C is a schematic of a specific implementation of the asynchronous circuit 1022 for controlling a switching converter 1026 in accordance with a sixth embodiment of the present disclosure.

In summary, embodiments of the present disclosure provide methods for the generation of asynchronous circuits that use circuit blocks to represent states of an AFSM, with arcs being represented by wires. Moving from state to state is by passing control from one circuit block to another, and there is no need to encode states, as is the case for the known system shown in FIG. 1B. Specifically, embodiments of the present disclosure transfer control between state blocks by having two state blocks communicating with one another. Compared with the known system, the method described herein is more intuitive and easier to understand for an engineer.

Furthermore, embodiments of the present disclosure may use single-rail signalling, which reduces the size of the circuit when compared to the system presented in FIG. 1B which uses dual rail signalling.

Embodiments of the present disclosure are easier to understand, teach, automate and debug when compared with known systems, and furthermore use lower area and have reduced latency when compared with known systems.

Many asynchronous controllers for analog circuitry are naturally specified as AFSMs, and therefore embodiments of the present disclosure are well suited for the design of asynchronous controllers.

Embodiments of the present disclosure are scalable, for example, due to the state control circuit block being a fixed-size circuit. Embodiments of the present disclosure enable scaling to many states whilst retaining low latency and low area.

In summary, embodiments of the present disclosure may provide asynchronous circuits having low latency, and a robustness to non-persistent inputs.

Common reference numerals and variables between Figures represent common features.

Various improvements and modifications may be made to the above without departing from the scope of the disclosure.

1. A computer-implemented method for generating a circuit design for an asynchronous circuit comprising an asynchronous finite state machine circuit, comprising executing on a processor:
receiving a first data file, the first data file comprising state transition data that describes an asynchronous finite state machine;
generating, from the state transition data:
a plurality of state data packages, each of the plurality of state data packages being representative of a state of the asynchronous finite state machine; and
one or more transition data packages, each of the one or more transition data packages being representative of a transition between two states of the asynchronous finite state machine; and
generating a second data file comprising circuit design data for the asynchronous circuit, thereby generating the circuit design for the asynchronous circuit, by:
for each of the plurality of state data packages, generating a circuit block data package comprising electrical circuit data for the design of an electrical circuit that is suitable for implementing an asynchronous finite state machine state as represented by the state data package;
generating a wire data package for each of the one or more transition data packages;
generating asynchronous finite state machine circuit data comprising the circuit block data packages and the wire data packages; and
generating the circuit design data comprising the asynchronous finite state machine circuit data.

2. The computer-implemented method of claim 1, wherein the state transition data comprises:
the plurality of state data packages; and/or
the one or more transition data packages.

3. The computer-implemented method of claim 1, wherein the asynchronous circuit is quasi delay insensitive.

4. The computer-implemented method of claim 1, wherein one of the circuit block data packages, as generated, comprises electrical circuit data for the design of an electrical circuit that is suitable for implementing an asynchronous finite state machine initial state.

5. The computer-implemented method of claim 1, wherein each of the circuit block data packages, as generated, comprises electrical circuit data that enables the electrical circuit to request a transition to another state of the asynchronous finite state machine.

6. The computer-implemented method of claim 5, wherein each of the circuit block data packages, as generated, comprises electrical circuit data that enables the electrical circuit to request a transition to another state of the asynchronous finite state machine when a condition is met.

7. The computer-implemented method of claim 6, wherein the condition is dependent on inputs as received by the asynchronous finite state machine circuit.

8. The computer-implemented method of claim 7, wherein the circuit design data comprises processing module data, the processing module data being data for the design of a processing module for processing the inputs prior to providing the inputs to the asynchronous finite state machine circuit.

9. The computer-implemented method of claim 8, wherein the processing module comprises one or more edge catching circuits, each of the one or more edge catching circuits being configured to process at least one of the inputs prior to providing the at least one input to the asynchronous finite state machine circuit by, for each of the at least one inputs, converting an edge into a level.

10. The computer-implemented method of claim 5, wherein the transition is requested via a wire to another electrical circuit, the wire being provided by one of the wire data packages.

11. The computer-implemented method of claim 6, wherein at least one of the circuit block data packages, as generated, comprises electrical circuit data for an arbiter circuit to arbitrate between a plurality of transition requests and then request the transition to another state of the asynchronous finite state machine when the condition is met and based on the arbitration.

12. The computer-implemented method of claim 5, wherein each of the circuit block data packages, as generated, comprises electrical circuit data that enables the electrical circuit to acknowledge that it has received a request from another state of the asynchronous finite state machine.

13. The computer-implemented method of claim 5 wherein each of the circuit block data packages, as generated, comprises electrical circuit data that enables the electrical circuit to initiate an action.

14. The computer-implemented method of claim 13, wherein the action is initiated by a handshake.

15. The computer-implemented method of claim 13, wherein the action comprises setting one or more outputs of the asynchronous circuit for controlling an analog circuit.

16. The computer-implemented method of claim 13, wherein the circuit design data comprises action processor data, the action processor data being data for the design of an action processor for performing the actions.

17. A computer system configured as an automated asynchronous circuit design tool for generating a circuit design for an asynchronous circuit comprising an asynchronous finite state machine circuit, the computer system being configured to:
receive a first data file, the first data file comprising state transition data that describes an asynchronous finite state machine;
generate, from the state transition data:
a plurality of state data packages, each of the plurality of state data packages being representative of a state of the asynchronous finite state machine; and
one or more transition data packages, each of the one or more transition data packages being representative of a transition between two states of the asynchronous finite state machine; and
generate a second data file comprising circuit design data for the asynchronous circuit, thereby generating the circuit design for the asynchronous circuit, by:
for each of the plurality of state data packages, generating a circuit block data package comprising electrical circuit data for the design of an electrical circuit that is suitable for implementing an asynchronous finite state machine state as represented by the state data package;
generating a wire data package for each of the one or more transition data packages;
generating asynchronous finite state machine circuit data comprising the circuit block data packages and the wire data packages; and
generating the circuit design data comprising the asynchronous finite state machine circuit data.

18. The computer system of claim 17, wherein the state transition data comprises:
the plurality of state data packages; and/or
the one or more transition data packages.

19. An asynchronous circuit comprising an asynchronous finite state machine circuit comprising:
a plurality of circuit blocks, wherein each of the circuit blocks is configured to implement a state of an asynchronous finite state machine; and
one or more wires, wherein each of the one or more wires is configured to enable communication between a pair of the circuit blocks for transitioning the asynchronous finite state machine between states.

20. The asynchronous circuit of claim 19, wherein each of the circuit blocks is configured to request a transition to another state of the asynchronous finite state machine.

21. The asynchronous circuit of claim 20, wherein the transition is requested via one of the wires.

22. The asynchronous circuit of claim 20, wherein at least one of the circuit blocks comprises an arbitration circuit configured to arbitrate between a plurality of transition requests.
